(19) United States
(12) Patent Application Publication
(10) Pub. No.: US 2024/0274414 A1
(43) Pub. Date: Aug. 15, 2024

(54) CHAMBER CLEAN FOR DRY DEVELOP OF METAL ORGANIC PHOTORESISTS

(71) Applicant: Applied Materials, Inc., Santa Clara, CA (US)

(72) Inventors: NEELA AYALASOMAYAJULA, Karnataka (IN); KELVIN CHAN, San Ramon, CA (US); VENUGOPAL VELLANKI, San Jose, CA (US); NIRANJANA BALESAN, Freemont, CA (US); ANDREW CONSTANT, Cupertino, CA (US); NASREEN CHOPRA, Santa Clara, CA (US)

(21) Appl. No.: 18/404,391

(22) Filed: Jan. 4, 2024

Related U.S. Application Data
(60) Provisional application No. 63/548,355, filed on Nov. 13, 2023.
(60) Provisional application No. 63/444,858, filed on Feb. 10, 2023.

(51) Int. Cl. H01J 37/32; G03F 7/00

(52) U.S. Cl. CPC H01J 37/32862; G03F 7/70925; H01J 37/32449; H01J 2237/184

(57) ABSTRACT

Embodiments disclosed herein include a method of cleaning a chamber. In an embodiment, the method comprises flowing a first processing gas into the chamber, where the first processing gas reacts with a metal-organic compound in the chamber to form a first volatile compound. In an embodiment, the method further comprises flowing a second processing gas into the chamber, where the second processing gas reacts with a pure metal of the metal-organic compound to form a second volatile compound. In an embodiment, the method further comprises removing the first volatile compound and the second volatile compound from the chamber.

### CROSS-REFERENCE TO RELATED APPLICATIONS

This application claims the benefit of U.S. Provisional Application No. 63/548,355, filed on Nov. 13, 2023, the entire contents of which are hereby incorporated by reference herein.

This application claims the benefit of U.S. Provisional Application No. 63/444,858, filed on Feb. 10, 2023, the entire contents of which are hereby incorporated by reference herein.

### BACKGROUND

### 1) Field

Embodiments of the present disclosure pertain to the field of semiconductor processing and, in particular, to cluster tools that integrate dry develop chambers for extreme ultraviolet lithography (EUV) and metrology tools for after develop inspection (ADI) and after etching inspection (AEI). Embodiments also relate to cleaning processes for removing metal-organic particles from processing chambers and load locks.

### 2) Description of Related Art

Lithography has been used in the semiconductor industry for decades for creating 2D and 3D patterns in microelectronic devices. The lithography process involves spin-on deposition of a film (photoresist), irradiation of the film with a selected pattern by an energy source (exposure), and removal (developing) of exposed (positive tone) or non-exposed (negative tone) region of the film by dissolving in a solvent. A bake will be carried out to drive off remaining solvent.

The photoresist should be a radiation sensitive material and upon irradiation a chemical transformation occurs in the exposed part of the film which enables a change in solubility between exposed and non-exposed regions. Using this solubility change, either exposed or non-exposed regions of the photoresist is removed (developed). Now the photoresist is developed and the pattern can be transferred to the underlying thin film or substrate by etching. After the pattern is transferred, the residual photoresist is removed and repeating this process many times can give 2D and 3D structures to be used in microelectronic devices.

Several properties are important in lithography processes. Such important properties include sensitivity, resolution, lower line-edge roughness (LER), etch resistance, and ability to form thinner layers. When the sensitivity is higher, the energy required to change the solubility of the as-deposited film is lower. This enables higher efficiency in the lithographic process. Resolution and LER determine how narrow features can be achieved by the lithographic process. Higher etch resistant materials are required for pattern transferring to form deep structures. Higher etch resistant materials also enable thinner films. Thinner films increase the efficiency of the lithographic process.

### SUMMARY

Embodiments disclosed herein include a method of cleaning a chamber. In an embodiment, the method comprises flowing a first processing gas into the chamber, where the first processing gas reacts with a metal-organic compound in the chamber to form a first volatile compound. In an embodiment, the method further comprises flowing a second processing gas into the chamber, where the second processing gas reacts with a pure metal of the metal-organic compound to form a second volatile compound. In an embodiment, the method further comprises removing the first volatile compound and the second volatile compound from the chamber.

Embodiments disclosed herein also include a method of cleaning a chamber with metal-organic deposits on one or more interior surfaces. In an embodiment, the method comprises flowing a first processing gas into the chamber, where the first processing gas comprises hydrogen, and wherein the hydrogen reacts with the metal-organic deposits to form first volatile species, and where at least some of the first volatile species decomposes to redeposit a pure metal on interior surfaces of the chamber. In an embodiment, the method further comprises flowing a second processing gas into the chamber, where the second processing gas comprises chlorine, and where the chlorine reacts with the pure metal to form a second volatile species.

Embodiments disclosed herein also include a load lock. In an embodiment, the load lock comprises a chamber with sidewalls, a top, and a bottom, and a plurality of slot regions for supporting substrates. In an embodiment, the load lock further comprises a remote plasma source (RPS), and a plurality of lines between the RPS and the chamber. In an embodiment, each line couples the RPS to one of the plurality of slot regions.

### BRIEF DESCRIPTION OF THE DRAWINGS

FIG. 1 is a schematic illustration of a lithography tool that includes a track for depositing a photoresist, a scanner for exposing the photoresist, and a metrology tool, in accordance with an embodiment.

FIG. 2 is a schematic illustration of a lithography tool that includes a dry develop chamber, an etch chamber, a metrology tool, and a dry deposition chamber, in accordance with an embodiment.

FIG. 3A is a plan view illustration of a cluster tool that comprises a metrology tool at the front end module side, develop chambers, and etch chambers, in accordance with an embodiment.

FIG. 3B is a plan view illustration of a cluster tool that comprises a metrology tool at an end opposite from the front end module, develop chambers, and etch chambers, in accordance with an embodiment.

FIG. 3C is a plan view illustration of a cluster tool that comprises a metrology tool coupled to the front end module, develop chambers, and etch chambers, in accordance with an embodiment.

FIG. 3D is a plan view illustration of a cluster tool that comprises a shared metrology tool between two rows of develop chambers and etch chambers, in accordance with an embodiment.

FIG. 3E is a plan view illustration of a cluster tool that comprises remote plasma sources coupled to the plurality of develop chambers, in accordance with an embodiment.

FIG. 3F is a plan view illustration of a cluster tool that comprises a metrology tool, develop chambers, etch chambers, and deposition chambers, in accordance with an embodiment.

FIG. 4A is a cross-sectional illustration of a substrate with an underlayer over a surface of the substrate, in accordance with an embodiment.

FIG. 4B is a cross-sectional illustration of the substrate after a photoresist layer is provided over the underlayer, in accordance with an embodiment.

FIG. 4C is a cross-sectional illustration of the substrate during exposure of the photoresist layer, in accordance with an embodiment.

FIG. 4D is a cross-sectional illustration of the substrate after the photoresist layer is developed, in accordance with an embodiment.

FIG. 4E is a cross-sectional illustration of the substrate during after develop inspection (ADI), in accordance with an embodiment.

FIG. 4F is a cross-sectional illustration of the substrate after the pattern in the photoresist layer is transferred into the underlayer and the substrate, in accordance with an embodiment.

FIG. 4G is a cross-sectional illustration of the substrate during after etch inspection (AEI), in accordance with an embodiment.

FIG. 5 is a process flow diagram of a photolithography process that is implemented at least in part in a cluster tool that includes a develop chamber, an etch chamber, and a metrology tool, in accordance with an embodiment.

FIG. 6 is a process flow diagram of a dry process for cleaning a chamber that includes metal-organic particulates, in accordance with an embodiment.

FIG. 7A is a plan view illustration of a cluster tool that includes a remote plasma source (RPS) that is coupled to a processing chamber and a load lock, in accordance with an embodiment.

FIG. 7B is a cross-sectional illustration of a load lock that is coupled to an RPS, in accordance with an embodiment.

FIG. 8 illustrates a block diagram of an exemplary computer system, in accordance with an embodiment of the present disclosure.

### DETAILED DESCRIPTION

Cluster tools that integrate dry develop chambers for extreme ultraviolet lithography (EUV) and metrology tools for after develop inspection (ADI) and after etching inspection (AEI) are described herein. In the following description, numerous specific details are set forth, such as thermal vapor phase processes and material regimes for developing photoresist, in order to provide a thorough understanding of embodiments of the present disclosure. It will be apparent to one skilled in the art that embodiments of the present disclosure may be practiced without these specific details. In other instances, well-known aspects, such as integrated circuit fabrication, are not described in detail in order to not unnecessarily obscure embodiments of the present disclosure. Furthermore, it is to be understood that the various embodiments shown in the Figures are illustrative representations and are not necessarily drawn to scale.

To provide context, photoresist systems used in extreme ultraviolet (EUV) lithography suffer from low efficiency. That is, existing photoresist material systems for EUV lithography require high dosages in order to provide the needed solubility switch that allows for developing the photoresist material. Chemically amplified resists (CARs) include chemistry that is sensitive to the EUV radiation. The chemical amplification concept uses a photochemically-generated acid as a catalyst. The catalyst induces a cascade of chemical transformations in the resist film, providing a gain mechanism to fully convert exposed regions of the photoresist. The converted regions of the CAR are then etch selective to the unexposed regions. As such, a developing process can be used to remove the exposed regions leaving the unexposed regions intact, or to remove the unexposed regions leaving the exposed regions intact.

Additional classes of photolithography resists that are suitable for EUV lithography are organic-inorganic hybrid materials (e.g., metal-oxo materials systems or metal-organic materials systems). Such material systems are beneficial for EUV lithography due to the increased sensitivity to EUV radiation. Such material systems typically comprise a metal (e.g., Sn, Hf, Zr, etc.), oxygen, and carbon. In a metal-oxo or metal-organic photoresist system, exposure to EUV radiation results in crosslinking and the removal of carbon. The difference in the carbon percentage between the exposed regions and the unexposed regions is used as the solubility switch during developing. Particularly, the unexposed regions with the higher carbon content are preferentially etched by the developer solution in a negative tone develop. Though, it is to be appreciated that a positive tone develop may also be used in some embodiments.

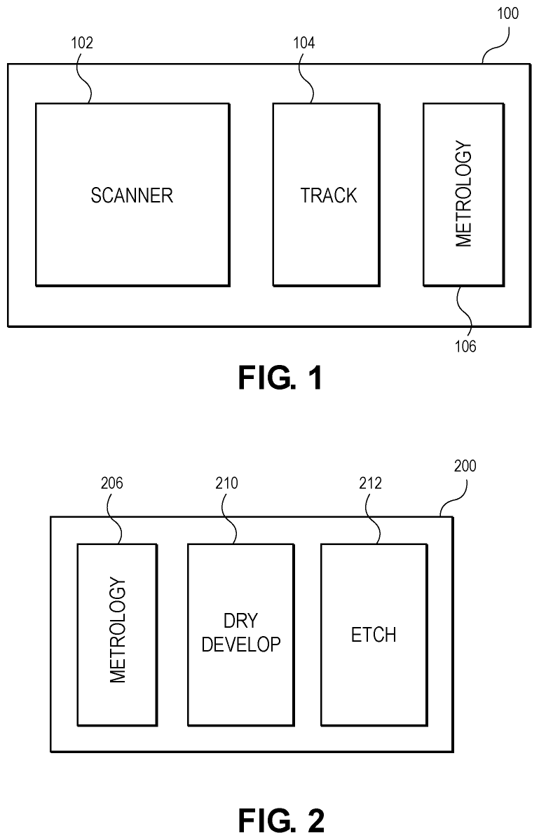

In many instances the resist deposition and exposure processes are provided in a single cluster tool, as shown in FIG. 1. For example, a tool 100 may be used to deposit and expose a resist. The tool 100 may comprise a track 104. The track 104 may include functionality in order to deposit the photosensitive resist material over the substrate. For example, the track 104 may dispense a liquid resist material over the substrate. The substrate is then spun at high revolutions per minute (RPM) in order to spread the resist material uniformly over the substrate. The track 104 may further comprise heating elements in order to bake the resist to prepare the resist for exposure.

The tool 100 may also include a scanner 102. The scanner 102 may be used to expose the resist to EUV radiation or other suitable radiation (e.g., deep ultraviolet (DUV)). The scanner 102 may be a stepper scanner, or any other suitable scanning technology. After exposure, the substrate may travel back to the track 104 where a post exposure bake (PEB) or the like may be implemented. The PEB may be used to drive the chemical reaction in the resist in some embodiments.

After the resist is processed through exposure, the resist needs to be developed. The developing process may be implemented on the track 104 which includes an etching environment. Typically, the developing is done with a wet etching chemistry. At small critical dimensions (CDs) and feature sizes the wet etching chemistry has a hard time developing the features due to surface tension effects in the wet etching chemistry.

After the developing process, the resulting structure is sent to a metrology tool for after develop inspection (ADI). As used herein, ADI may refer to operations such as one or more of critical dimension (CD) metrology, overlay metrology, and defect inspection. In some instances, the tool 100 may also comprise a metrology tool 106 in order to inspect the resist after the exposure, the PEB, and developing. The metrology tool 106 may include functionality to image or otherwise analyze the resist. For example, the metrology tool 106 may include scatterometry or any other pertinent metrology system, such as CD-secondary electron microscopy (CD-SEM). If the inspection meets all requirements, the substrate is sent to an etching chamber in order to transfer the pattern in the resist into the underlying substrate. The etching chamber may be provided in another tool. Therefore, a trip in a front opening unified pod (FOUP) may be required, and the substrate will leave the vacuum condition. After etching, the substrate may be sent to a metrology tool again in order to perform after etch inspection (AEI). The AEI may include both after etch metrology (e.g., CD-SEM, scatterometry, etc.) and defect inspection. The defect inspection may be done on a standalone tool, such as a bright field inspection tool.

As can be appreciated from the process flow described above, the substrate needs to traverse between multiple tools and chambers in order to fully pattern a substrate using EUV lithography processes. Accordingly, embodiments disclosed herein include cluster tool architectures that enable resist development, pattern transfer, and metrology all within a single tool architecture. More particularly, the develop process may be executed with a dry develop process, which allows for finer CDs and feature sizes. The all-in-one cluster tool may allow for both ADI and AEI without leaving the vacuum environment. This enables faster processing, improved outcomes, and other efficiencies.

Further, embodiments disclosed herein leverage dry cleaning processes that can be used to periodically clean chambers, load locks, and the like. During the processing of photoresist systems, particulates may deposit onto the surfaces of chambers. Without cleaning, the particulates may redeposit on subsequently processed substrates and result in defects or other damage. In the case of a metal-organic photoresist system, the particulates will generally include a metal-organic compound. Existing cleaning processes (e.g., using NF₃) will not result in volatile compounds that can be removed from the chamber, especially when the metallic component comprises tin. Accordingly, new cleaning process flows are disclosed herein.

Generally, a first processing gas (with or without plasma) is flown into the chamber. The first processing gas volatizes the metal-organic particulates, which can be evacuated from the chamber. However, some amount of pure metal may redeposit onto surfaces of the chamber. Accordingly, a second processing gas (with or without plasma) is flown into the chamber to react with the pure metal to form a volatile compound that can be removed from the chamber. In some embodiments, the first processing gas and the second processing gas may include one or more of hydrogen, chlorine, and bromine. Oxygen and inert gasses (e.g., argon, helium, nitrogen, etc.) may also be added to the processing gasses in some embodiments.

Referring now to FIG. 2, a schematic illustration of a cluster tool 200 is shown, in accordance with an embodiment. In an embodiment, the cluster tool 200 may comprise a develop chamber 210. More particularly, the develop chamber 210 may be a dry develop chamber 210. As such, the exposed resist layer can be developed with a dry etching process that improves LER, LWR, CD, and overall feature sizes. The develop chamber 210 may be any suitable chamber for dry developing processes. For example, the dry develop chamber 210 may be a plasma chamber. The plasma is struck and the plasma reacts with and removes either the exposed or unexposed regions of the resist, depending on if the resist is a positive resist or a negative resist.

In an embodiment, the cluster tool 200 may further include an etch chamber 212. The etch chamber 212 may also be a plasma etching device. The etch chamber 212 implements a dry etching process in order to transfer the pattern of the resist layer into an underlying layer of the substrate (e.g., a silicon layer, an oxide layer, a nitride layer, a metal layer, or any other layer suitable for semiconductor processing). In a more particular embodiment, the underlying layer may include any number of layers. For example, the underlying layer may include a hardmask (e.g., tin based), a hardmask (e.g., silicon carbide), and a device stack that needs to be patterned.

In an embodiment, the cluster tool 200 may further comprise a metrology tool 206. The metrology tool 206 may be used to detect overlay error, LER, LWR, CD, or any other parameter of a resist or patterned substrate. In a particular embodiment, the cluster tool 200 may include a scatterometry tool. The metrology tool 206 may be used in order to provide ADI or AEI. Since the metrology tool 206 is integrated with the etch chamber 212 and the develop chamber 210 in the cluster tool 200, there is no need for the substrate to leave the vacuum environment during processing.

As one generic example of a potential process flow through the cluster tool, the process may begin with the pattern being formed in the resist with the dry develop chamber 210. Thereafter, ADI may be implemented by the metrology tool 206. Etching of the substrate then proceeds in the etch chamber 212. In some embodiments, the etch chamber 212 may etch the underlayer and the hardmask in the same chamber. After etching the underlayer and the hardmask, AEI is implemented by the metrology tool 206 in order to confirm the etched pattern is adequately formed. When confirmed, the substrate can be transferred back to the etch chamber 212 for additional etching in order to etch into the device stack.

In an embodiment, the cluster tool 200 may further comprise a dry deposition tool 215. The dry deposition tool 215 may be used in order to coat the resist onto the substrate using a deposition process such as chemical vapor deposition (CVD), atomic layer deposition (ALD) or the like.

In an embodiment, the cluster tool 200 is generically shown as a simple box, and there are no connections between the metrology tool 206, the develop chamber 210, and the etch chamber 212. However, as will be described in greater detail below, there are transfer chambers and the like between the components. For example, load locks, a robot transfer chamber, and the like may be provided between chambers and tools in the cluster tool 200. There may also be an equipment front end module (EFEM) to receive FOUPs and the like. Further, while several chamber types are included in FIG. 2, it is to be appreciated that embodiments may include only the metrology tool 206 and the dry develop chamber 210.

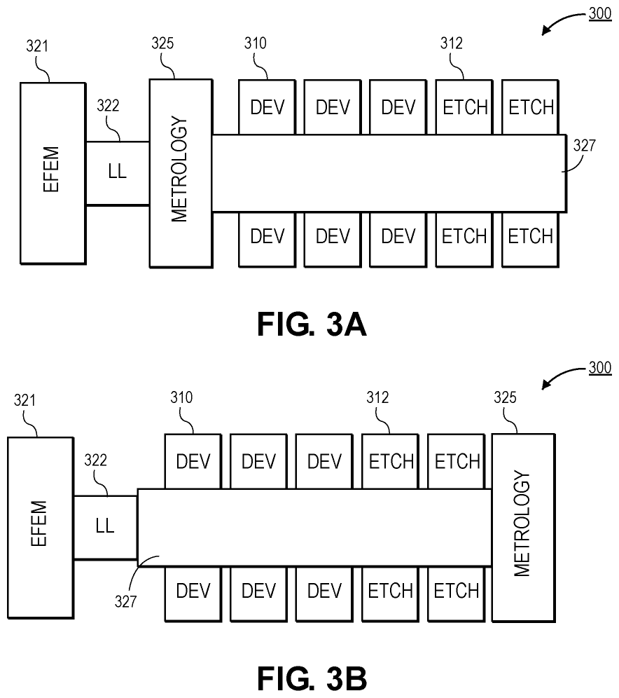

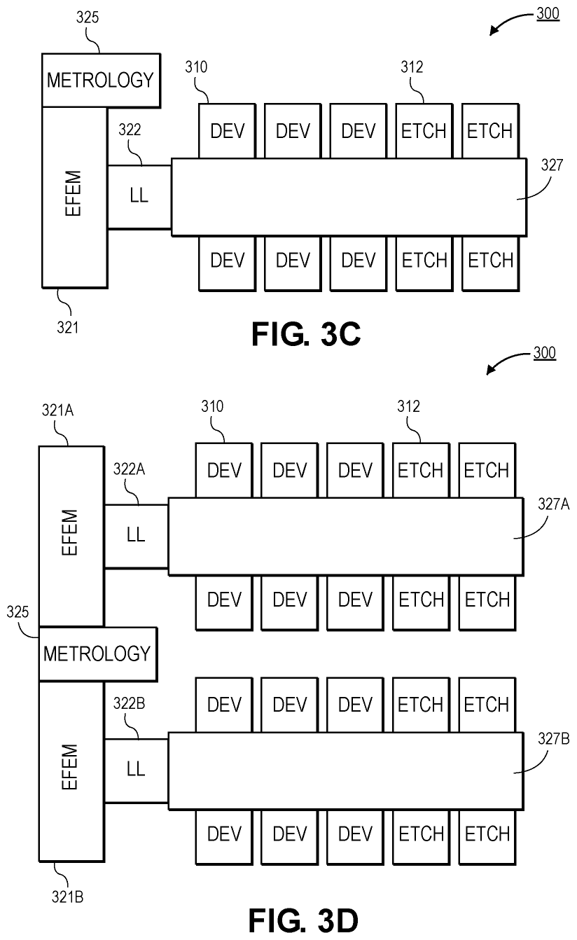

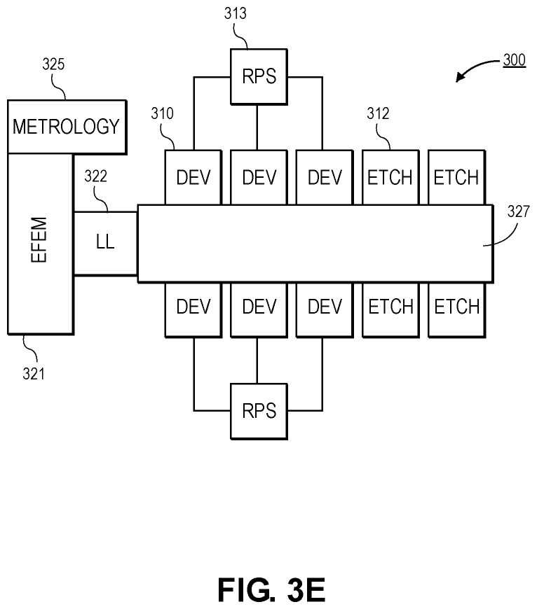

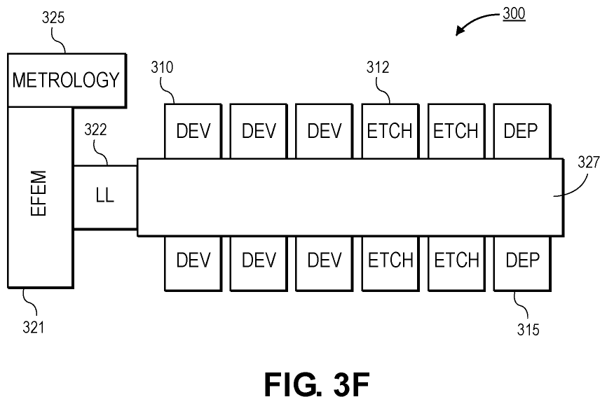

Referring now to FIGS. 3A-3F, a series of plan view illustrations depicting the layout of various cluster tools 300 is shown, in accordance with an embodiment. As will be appreciated from the description below, the individual components (e.g., metrology tool, develop chamber, etch chamber, etc.) may be arranged in many different configurations, while still maintaining the benefits of being part of a single cluster tool architecture. The following cluster tools 300 are shown schematically with generic boxes. Those skilled in the art will recognize that complex features (e.g., slit valves, pumping solutions, robot handling equipment, plasma sources, and the like) are omitted in order to more clearly depict the general layout of the cluster tools 300.

Referring now to FIG. 3A, a plan view illustration of a cluster tool 300 is shown, in accordance with an embodiment. In an embodiment, the cluster tool 300 may comprise an EFEM 321. The EFEM 321 may receive FOUPs, cassettes, or the like as an entry point for substrates into the cluster tool 300. The substrates that are processed in the cluster tool 300 may include wafers (e.g., silicon wafers, or other semiconductor wafers) with any standard form factor, (e.g., 200 mm, 300 mm, 450 mm, etc.). In an embodiment, the EFEM 321 may be coupled to the rest of the cluster tool 300 through a load lock 322. The load lock 322 may separate an atmospheric condition in the EFEM from a vacuum condition in the rest of the cluster tool 300. Though, in some embodiments, the EFEM may also be under a vacuum pressure (e.g., a higher pressure than on the other side of the load lock 322).

In an embodiment, a metrology tool 325 may be provided after the load lock 322. The metrology tool 325 may be a scatterometry tool or any other metrology tool useful for ADI or AEI applications. In an embodiment, the metrology tool 325 may be communicatively coupled with a transfer chamber 327. The transfer chamber 327 may include robotic arms, tracks, or any suitable architecture for transporting the substrates between the metrology tool 325 and the remainder of the cluster tool 300.

In an embodiment, one or more develop chambers 310 and one or more etch chambers 312 may be coupled to the transfer chamber 327. For example, six develop chambers 310 and four etch chambers 312 are provided in the cluster tool 300. The chambers 310 and 312 may be provided on two sides of the transfer chamber 327 in order to optimize space savings. In an embodiment, the develop chambers 310 may be dry develop chambers. A plasma source may be used in conjunction with the develop chambers 310 in order to develop the resist layers without any wet chemistries. Though, it is to be appreciated that dry development processes do not require plasma sources. That is, the dry develop process may or may not use a plasma source. In the case where a plasma source is not used, the dry develop process may be a thermal dry develop process in some embodiments. The plasma source may also be used to clean the develop chambers 310 and reduce tin contamination. For example, a plasma etching chemistry comprising one or more of F₂, NF₃, Cl₂, O₂, and HBr may be used in order to clean the develop chambers 310 in some embodiments. Further, while tin contamination is provided as one example of a material to be cleaned from the chamber, it is to be appreciated that other metals may also pose contamination risk. As such, other metals may also be cleaned using a plasma source, depending on the type of photoresist material that is being used. Additionally, the etch chambers 312 may be dry etching chambers 312 that use plasma to etch the substrate through the resist layer.

In an embodiment, the substrate may enter the EFEM, pass through the load lock 322 and the metrology tool 325 and be delivered to one of the develop chambers 310. After developing, the substrate may be delivered to the metrology tool 325 for ADI. After ADI, the substrate may be delivered to one of the etch chambers 312 through the transfer chamber 327. There, the substrate may be etched through the developed resist layer. The substrate may then be transferred back to the metrology tool 325 for AEI. Accordingly, the operations of resist development, ADI, substrate etching, and AEI may occur within a single cluster tool 300 without needing to leave a vacuum environment.

Referring now to FIG. 3B, a plan view illustration of a cluster tool 300 is shown, in accordance with an additional embodiment. The cluster tool 300 may be similar to the cluster tool 300 described in greater detail above, with the exception of the metrology tool 325. Instead of being between the load lock 322 and the transfer chamber 327, the metrology tool 325 is on an end of the cluster tool 300 opposite from the EFEM 321. That is, the load lock 322 may directly couple with the transfer chamber 327. Such an embodiment allows for the substrate to be inserted and removed from the cluster tool 300 without having to pass through the metrology tool 325. While shown at the end of the transfer chamber 327, it is to be appreciated that the metrology tool 325 may be coupled to the transfer chamber 327 at any location along the transfer chamber 327.

Referring now to FIG. 3C, a cross-sectional illustration of a cluster tool 300 is shown, in accordance with an additional embodiment. In an embodiment, the cluster tool 300 in FIG. 3C may be similar to the cluster tool 300 in FIG. 3A, with the exception of the positioning of the metrology tool 325. In an embodiment, the metrology tool 325 may be directly coupled to the EFEM 321. For example, the metrology tool 325 may be provided along an edge of the EFEM 321. This allows substrates to be transferred from a FOUP directly to the metrology tool 325 through the EFEM 321 without needing to pass through the load lock 322. In an embodiment, the develop chambers 310 and the etch chambers 312 may be on the opposite side of the load lock 322 relative to the metrology tool 325. In some embodiments, developing of the resist and etching the substrate may both be done before the substrate passes back through the load lock 322 to the metrology tool 325.

Referring now to FIG. 3D, a plan view illustration of a cluster tool 300 is shown, in accordance with an additional embodiment. In the embodiment shown in FIG. 3D, the metrology tool 325 is shared between a first processing line and a second processing line. The first processing line may include a first EFEM 321A, a first load lock 322A, and a first transfer chamber 327A. Develop chambers 310 and etch chambers 312 may be coupled to the first transfer chamber 327A. The second processing line may include a second EFEM 321B, a second load lock 322B, and a second transfer chamber 327B. Develop chambers 310 and etch chambers 312 may be coupled to the second transfer chamber 327B. As shown, the metrology tool 325 is coupled to both the first EFEM 321A and the second EFEM 321B. The overall structure of the cluster tool 300 may be U-shaped, with the first processing line forming a first arm, the second processing line forming a second arm, and the metrology tool 325 forming the branch between the first arm and the second arm.

Referring now to FIG. 3E, a plan view illustration of a cluster tool 300 is shown, in accordance with an additional embodiment. The cluster tool 300 in FIG. 3E may be similar to the cluster tool 300 in FIG. 3C, with the addition of a remote plasma source (RPS) 313. As shown, a pair of RPS's 313 may be coupled to the cluster tool 300. For example, each of the RPS's 313 may be fluidically coupled to a plurality of develop chambers 310. Moving the plasma source from the develop chambers to the RPS 313 allows for the develop chambers 310 to be simplified, and a single RPS 313 can be used for multiple develop chambers 310, which further simplifies the design and maintenance of the cluster tool 300. While not shown as including an RPS 313, it is to be appreciated that RPS 313 solutions may also be used in order to provide plasma to the one or more etch chambers 312. The RPS 313 may be used to aid in the developing process of the develop chambers 310. Though, in other embodiments, the develop process is a dry process without a plasma, such as a thermal dry develop process. In such cases, the RPS 313 may be used for cleaning the develop chambers 310. For example, plasma chemistries comprising one or more of F₂, NF₃, Cl₂, O₂, and HBr may be used in order to clean the develop chambers 310 in some embodiments.

Referring now to FIG. 3F, a plan view illustration of a cluster tool 300 is shown, in accordance with an additional embodiment. The cluster tool 300 in FIG. 3F may be substantially similar to the cluster tool 300 in FIG. 3C with the addition of one or more deposition chambers 315. In an embodiment, the deposition chambers 315 may be used to deposit the photolithography resist layer onto the substrate. In order to minimize waste, improve resist uniformity, and/or provide compositional gradients through the thickness of the resist layer, the deposition chambers 315 may be dry deposition chambers. For example, an atomic layer deposition (ALD) process or a chemical vapor deposition (CVD) process may be used to deposit the resist layer. In an embodiment, one or more metal containing precursors (and optionally an oxidant) may be reacted in the deposition chambers 315 in order to deposit the resist layer on the substrate. The resist layer may be a chemically amplified resist (CAR) system or a metal-oxo resist system.

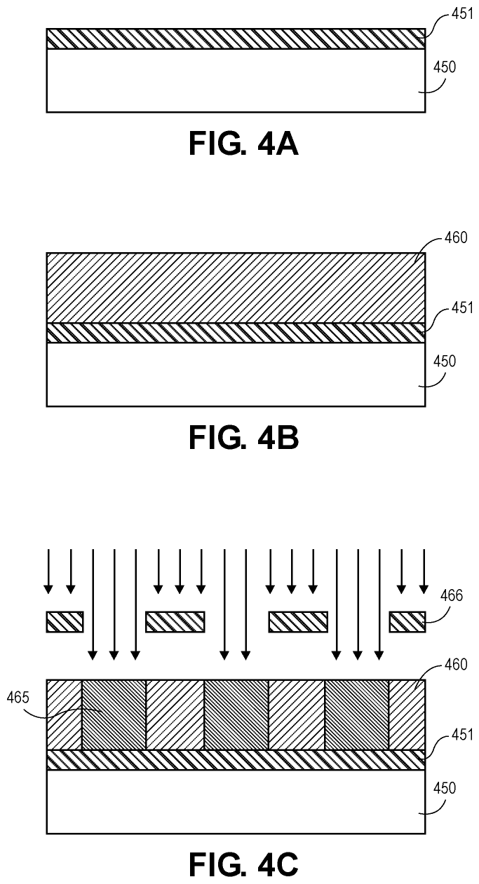

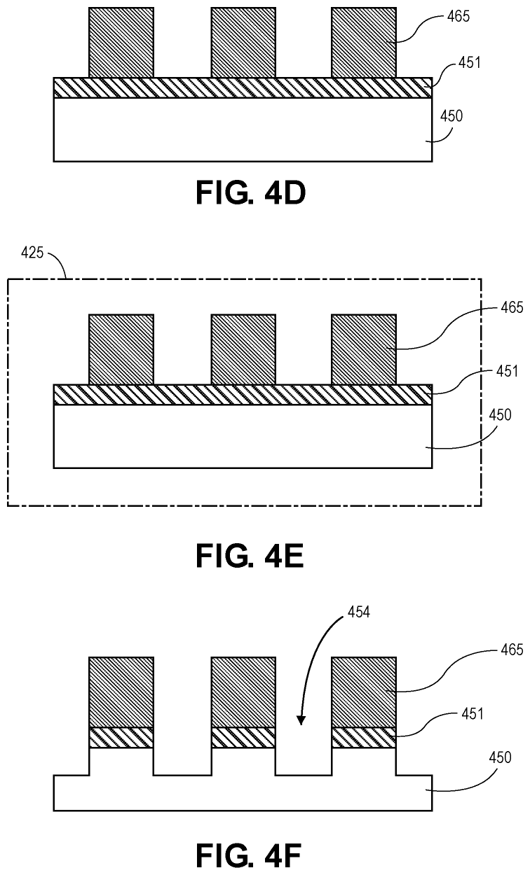

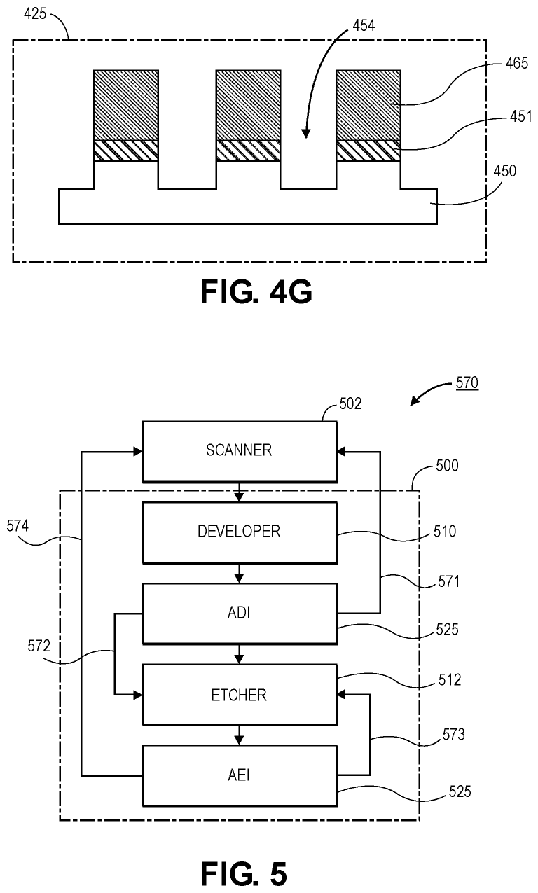

Referring now to FIGS. 4A-4G, a process for forming a pattern in a substrate using a cluster tool is shown, in accordance with an embodiment. In an embodiment, the pattern may be transferred into a substrate using an exposed and developed photoresist layer. The photoresist layer may be a CAR or a metal-oxo resist in some embodiments. In a particular embodiment, the processing may include EUV exposure, DUV exposure, or any other suitable electromagnetic radiation.

Referring now to FIG. 4A, a cross-sectional illustration of a substrate 450 is shown, in accordance with an embodiment. In an embodiment, the substrate 450 may be a semiconductor substrate, such as a silicon wafer or the like. The illustrated substrate 450 may also be any layer that is used in semiconductor manufacturing environments. For example, the substrate 450 may comprise an oxide, a nitride, a metal, or any other material composition that needs to be patterned with an lithography operation. In an embodiment, an underlayer 451 may be provided over a top surface of the substrate 450. The underlayer 451 may be a material that enhances the etching of the substrate 450. In some embodiments, the underlayer 451 may be a hardmask layer or the like.

Referring now to FIG. 4B, a cross-sectional illustration of the substrate 450 after a resist layer 460 is provided over the underlayer 451 is shown, in accordance with an embodiment. In an embodiment, the resist layer 460 may be a CAR system or a metal-oxo system. The resist layer 460 may be deposited with a wet coating process (e.g., spin coating) or a dry coating process (e.g., ALD or CVD). In an embodiment, the coating process may be done in a cluster tool or as part of a track coupled to the lithography tool.

Referring now to FIG. 4C, a cross-sectional illustration of the substrate 450 during exposure is shown, in accordance with an embodiment. In an embodiment, the exposure is made through a mask 466. The exposure may be EUV, DUV, or the like. The portions of the exposure (indicated with arrows) that pass through the mask 466 react with the resist 460 to form exposed regions 465. The exposed regions may be fully converted in order to be etch selective to the remainder of the resist 460. In some embodiments, a post exposure bake (PEB) may be used to fully convert the exposed regions 465.

Referring now to FIG. 4D, a cross-sectional illustration of the substrate 450 after the resist 460 is developed is shown, in accordance with an embodiment. In an embodiment, the developing process may be done in a cluster tool, such as cluster tools 300 described in greater detail above. The developing process may be a dry develop process which may or may not include the use of a plasma. The dry developing process may result in the unexposed regions being removed. Though, the exposed regions 465 may optionally be removed instead of the unexposed regions of the resist 460 in an opposite tone resist.

Referring now to FIG. 4E, a cross-sectional illustration of the substrate 450 when the substrate is provided in a metrology tool 425 is shown, in accordance with an embodiment. The metrology tool 425 may be part of the cluster tool that includes the develop chamber. As such, the substrate 450 may not need to be removed from a vacuum environment in order to execute ADI processes. The ADI may include scatterometry or any other type of metrology used to inspect the result of the developing process.

Referring now to FIG. 4F, a cross-sectional illustration of the substrate 450 after a pattern transfer process is shown, in accordance with an embodiment. In an embodiment, the pattern transfer process may be implemented in an etch chamber that is coupled to the metrology tool 425 and the develop chamber. The etch chamber may be a dry etching chamber that uses a plasma to etch the underlayer 451 and the substrate 450 to form features 454 (e.g., trenches, lines, etc.). While referred to as an “etch chamber” it is to be appreciated that the pattern transfer process may include both etching and deposition processes (e.g., sidewall deposition processes).

Referring now to FIG. 4G, a cross-sectional illustration of the substrate 450 after the substrate is moved to a metrology tool 425 is shown, in accordance with an embodiment. The metrology tool may be the same tool used for the ADI. Though, embodiments may also include a different metrology tool 425 than the one used for the ADI. The metrology tool 425 shown in FIG. 4G may be used in order to conduct AEI. The metrology may include scatterometry or the like. After AEI, the substrate 450 may be removed from the cluster tool for additional processing or inspection.

Referring now to FIG. 5, a flow diagram of a process 570 is shown, in accordance with an embodiment. In an embodiment, the process 570 may begin with an exposure process of a photoresist. The exposure process may be done in a scanner 502, such as an EUV or DUV scanner. After the resist layer is exposed, it may be baked or otherwise processed. The substrate with the exposed photoresist is then transferred to a cluster tool 500. The cluster tool 500 may include a developer 510, such as a develop chamber. The developer 510 may be a dry develop tool that uses a plasma to develop the exposed photoresist.

After developing, the substrate may be moved to a metrology tool 525 for ADI. The ADI may provide feedback 571 that is provided back to the scanner 502 in order to improve the performance of the scanner 502. Additionally, the ADI may provide feed forward data 572 to the etcher 512. The feed forward data may be used to control the etching process in order to account for certain errors in the developing process. The metrology tool 525 may also be in the cluster tool 500.

After ADI, the substrate is sent to the etcher 512. The etcher 512 may be provided in the cluster tool 500. The etcher 500 transfers the pattern of the photoresist into the substrate. For example, a dry etching process may be used in some embodiments.

After etching, the substrate is sent back to a metrology tool 525 for AEI. The AEI process may provide feedback 573 back to the etcher 512 and/or feedback 574 that is provided back to the scanner 502. In-line measurements (e.g., either ADI or AEI) offer denser sampling, as well as faster feedback and/or feed forward loops. According, the cluster tools described herein increase the accuracy and speed of processing substrates compared to conventional processes.

The feedback and feed forward process loops may be suitable for any type of system control. In one embodiment, automated process control (APC) may be implemented with a process similar to the one described above with respect to FIG. 5. Similarly, fault defect classification (FDC) may be implemented using a process similar to the process described above with respect to FIG. 5.

As noted above, the processing of photoresist systems (e.g., developing, etc.) may result in the formation of particulate depositions on the surfaces of the chambers. Without periodic and proper cleaning, these particulates can become the source of damage or defects in subsequently processed substrates. Accordingly, embodiments disclosed herein include cleaning processes that can be used in order to reduce or eliminate particle redeposition onto substrates.

Generally, the cleaning processes described herein can be characterized as dry cleaning processes. That is, the cleaning is implemented through the use of one or more processing gasses. In some embodiments, the processing gasses are radicalized through the use of a plasma. The plasma may be any type of plasma. For example, plasmas may include an in-situ plasma source, a remote plasma source (RPS), a microwave plasma source, a capacitively coupled plasma (CCP) source, an inductively coupled plasma (ICP) source, a transformer-coupled toroidal plasma (TCTP) source, or the like. Though, thermal cleaning operations (i.e., without plasma) may also be used in some embodiments.

In an embodiment, the cleaning process may be provided in any of the chambers within a cluster tool similar to any cluster tools described in greater detail herein. In a particular embodiment, the cleaning process may be carried out in a photoresist developing chamber. Other embodiments may use a cleaning process to clean chambers used to transfer substrates, such as a load lock or a transfer chamber.

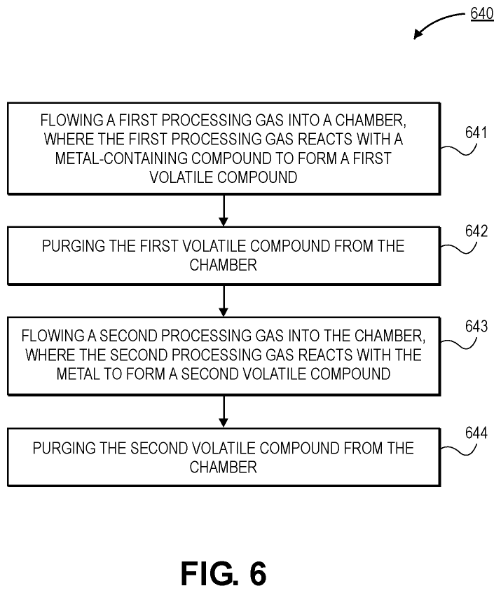

Referring now to FIG. 6, a process flow diagram illustrating a process 640 for cleaning a chamber is shown, in accordance with an embodiment. In an embodiment, the process 640 may be implemented at any desired frequency. For example, the process 640 may be executed after a certain number of substrates are processed (e.g., 1 substrate, 5 substrates, 20 substrates, etc.), after a certain duration of time (e.g., every hour, every 3 hours, at the start of a shift, every day, etc.), after detection of contaminates on a processed substrates, or after any other duration or suitable criteria are met.

In an embodiment, the process 640 may be targeted at cleaning metal-organic compounds that are deposited onto surfaces of the chamber. The metal-organic compounds may originate from a photoresist system. The photoresist system may be a DUV or EUV photoresist, such as a metal-oxo system, a metal-organic system, or the like. In an embodiment, the metallic component may comprise one or more of Sn, Hf, Zr, or other suitable metallic elements. The metal may be bonded to organic elements, (e.g., carbon, oxygen, hydrogen, nitrogen, etc.). Processing gasses that may be suitable for removing the metallic component may include hydrogen, chlorine, bromine, and the like.

In an embodiment, the process 640 may begin with operation 641 which comprises flowing a first processing gas into the chamber. In an embodiment, the first processing gas reacts with the metal-containing compounds to form a first volatile compound. The first processing gas may comprise hydrogen, chlorine, chlorine trifluoride, or bromine. The use of hydrogen may be particularly beneficial in the case of tin-based metal-organic compounds. The hydrogen (H₂) may react with the tin to form SnH₄, which is a volatile compound through the chemical reaction Sn+2H₂→SnH₄. The hydrogen may also preferentially react with the organic components in order to form volatile species. For example, 2H+SnO→Sn+H₂O. Unfortunately, SnH₄ will tend to spontaneously decompose into pure Sn through the chemical reaction SnH₄→Sn+2H₂. Though, decomposition may also lead to other Sn-containing materials as well through reactions with other species in the chamber. As such, process 640 may include additional operations, as will be described in greater detail below.

In an embodiment, the hydrogen may be flown into the chamber with a thermal process that does not include a plasma activation. Alternatively, a plasma may be used in order to radicalize the hydrogen in order to improve the reactivity with the metal-organic compounds. The plasma source may be any suitable plasma source, such as those described in greater detail above. In embodiments with an RPS, oxygen may be flown with the hydrogen in order to improve the radicalization of the hydrogen within the RPS. Inert gasses (e.g., argon, helium, nitrogen, etc.) may also be flown with the hydrogen to support a more robust plasma.

In an embodiment, the process 640 may continue with operation 642, which comprises purging the first volatile compound from the chamber. The first volatile compound may be purged with any suitable exhaust or vacuum pump configuration. The first volatile compound may include hydrogen reacted with organic compounds and with some amount of the metallic element (e.g., tin). Though, as described above, some amount of the pure metallic element (in a solid form) or other metallic-containing solids may remain in the chamber.

In an embodiment, the process 640 may continue with operation 643, which comprises flowing a second processing gas into the chamber. The second processing gas reacts with the metal to form a second volatile compound. In an embodiment, the second processing gas is a different processing gas than the first processing gas. For example, when the first processing gas comprises hydrogen, the second processing gas may comprise chlorine, chorine trifluoride, or bromine. In the case of chlorine, the chemical reaction may include Sn+Cl₂→SnCl₄, with SnCl₄ being a volatile compound. In an embodiment, operation 643 may be implemented with a plasma or without a plasma (e.g., a thermal cleaning operation). The second processing gas may be include chlorine only, or the second processing gas may include chlorine with oxygen and/or an inert gas (e.g., argon, helium, nitrogen, etc.).

In an embodiment, the process 640 may continue with operation 644, which comprises purging the second volatile compound from the chamber. The second volatile compound may be purged with any suitable exhaust or vacuum pump configuration. The second volatile compound may include chlorine reacted with the pure metallic element (e.g., tin) or other metallic-containing material.

In an embodiment, the process 640 may be run sequentially. That is, operations 641-644 may be executed one after another. For example, a first pulse of the first processing gas may be flown into the chamber followed by a second pulse of the second processing gas. The purge operation 642 between the two pulses may also be omitted in some embodiments. In an embodiment, the first pulse and the second pulse may be the same duration, or the first pulse and the second pulse may have different durations. Durations for the first pulse and the second pulse may range from several seconds to one or more minutes (e.g., 1 minute, 5 minutes, 10 minutes, etc.). In an embodiment, the process 640 may be repeated any number of times as well. For example, operations 641-644 may be cycled through two or more times in order to provide a desired level of cleaning. While sequential processes may be beneficial for some cleaning operations, embodiments may also include flowing both the first processing gas and the second processing gas at the same time.

In an embodiment, the processing conditions used during the cleaning process 640 may be similar to those used to process the substrates. As such, there is no need to significantly change temperature or pressure during cleaning. This allows for faster cleaning operations and improved throughput. For example, temperatures during process 640 (e.g., a wafer temperature) may be between approximately 20° ° C. and approximately 100° ° C., and pressures during process 640 may be between approximately 1 mTorr and approximately 10 Torr. Processing gas flow rates may be between approximately 10 sccm and 5,000 sccm during operations 641-644.

In the embodiment shown in FIG. 6, the process 640 includes the flow of two separate processing gasses. Though, in other embodiments, sufficient cleaning may be obtained through the use of a single processing gas. For example, the use of radicalized hydrogen may be sufficient to remove a desired amount of residual deposits on the chamber surfaces. Longer cleaning durations (compared to a two gas process) may be necessary, or a single gas process may be executed more frequently.

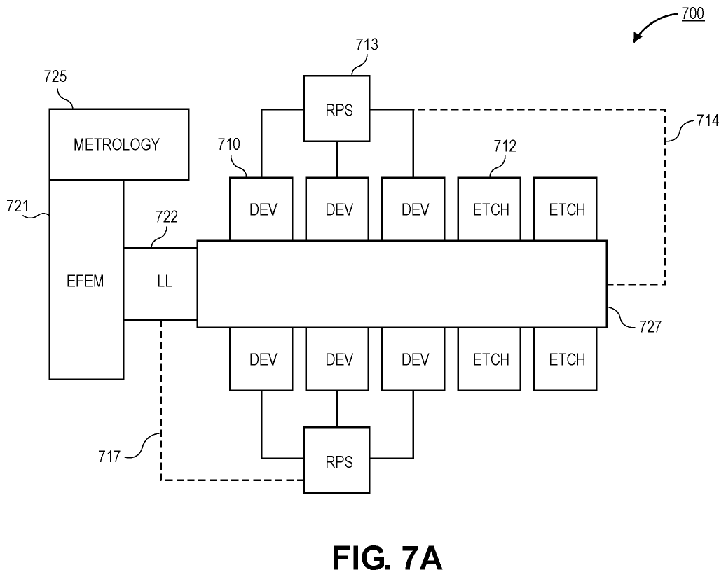

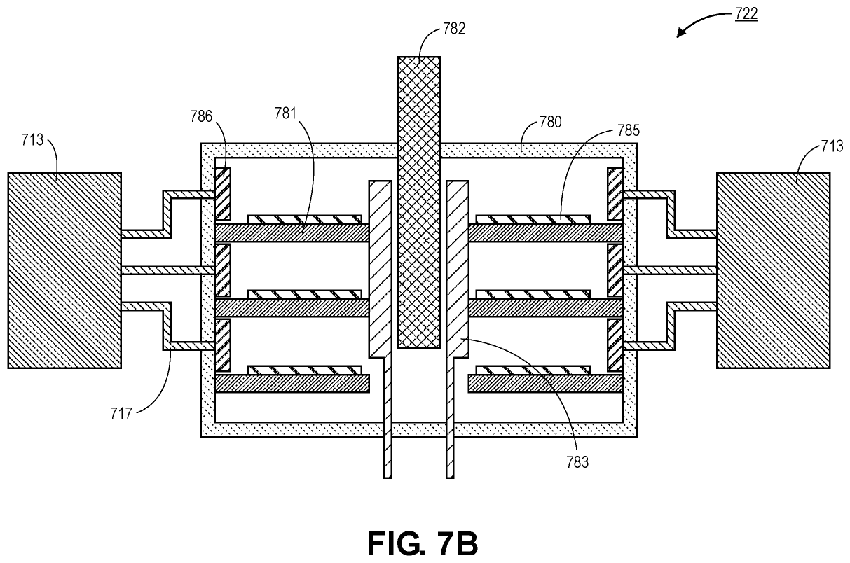

Referring now to FIG. 7, a plan view illustration of a cluster tool 700 is shown, in accordance with an additional embodiment. The cluster tool 700 in FIG. 7 may be similar to the cluster tool 700 in FIG. 3E, with the addition of the RPS 713 being coupled to the load lock 722 and the transfer chamber 727 by lines 717 and 714, respectively. That is, the cluster tool 700 may include an EFEM 721 and metrology tool 725 that are coupled to the transfer chamber 727 through the load lock 722. Develop chambers 710 and etching chambers 712 may also be coupled to the transfer chamber 727.

As shown, a pair of RPS's 713 may be coupled to the cluster tool 700. For example, each of the RPS's 713 may be fluidically coupled to a plurality of develop chambers 710. Moving the plasma source from the develop chambers to the RPS 713 allows for the develop chambers 710 to be simplified, and a single RPS 713 can be used for multiple develop chambers 710, which further simplifies the design and maintenance of the cluster tool 700. While not shown as including an RPS 713, it is to be appreciated that RPS 713 solutions may also be used in order to provide plasma to the one or more etch chambers 712. The RPS 713 may be used to aid in the developing process of the develop chambers 710. Though, in other embodiments, the develop process is a dry process without a plasma, such as a thermal dry develop process.

In some embodiments, the RPS 713 may be used for cleaning the develop chambers 710, the load lock 722, the etch chambers 712, or the transfer chamber 727. For example, a cleaning process, such as process 640 may be implemented through the use of the RPS 713 in order to provide periodic cleaning of one or more of the develop chambers 710, the load lock 722, the etch chambers 712, and the transfer chamber 727. That is, a sequence of two processing gasses (e.g., hydrogen followed by chlorine) may be used in order to clean metal-organic deposits on the interior chamber surfaces, similar to embodiments described in greater detail above.

Referring now to FIG. 7B, a cross-sectional illustration of a portion of a load lock 722 is shown, in accordance with an embodiment. The load lock 722 may include a chamber 780. The chamber 780 may be divided into a plurality of slot regions by supports 781. The substrates 785 may rest on the supports 781. A robot arm 782 may be provided within the load lock 722 to move substrates 785 into and out of the load lock 722. Pumping features 783 (e.g., exhaust, vacuums, etc.) may also be provided within the load lock 722.

The presence of multiple supports 781 makes it difficult to clean the many regions of the load lock 722 with conventional cleaning solutions. However, since an RPS 713 solution is used, multiple feeds can be provided into the chamber 780. For example, each slot region can be supplied with a dedicated feed line 717. In an embodiment, a distribution plate 786 is provided at the end of each of the feed lines 717 in order to more uniformly distribute the radicalized species from the plasma. In the illustrated embodiment, the feed lines 717 enter into the chamber 780 through sidewalls. As such, each of the slot regions can be accessed without shadowing from overlying supports 781, as would be the case if the feed lines 717 were introduced from the top of the chamber 780 using a more conventional approach.

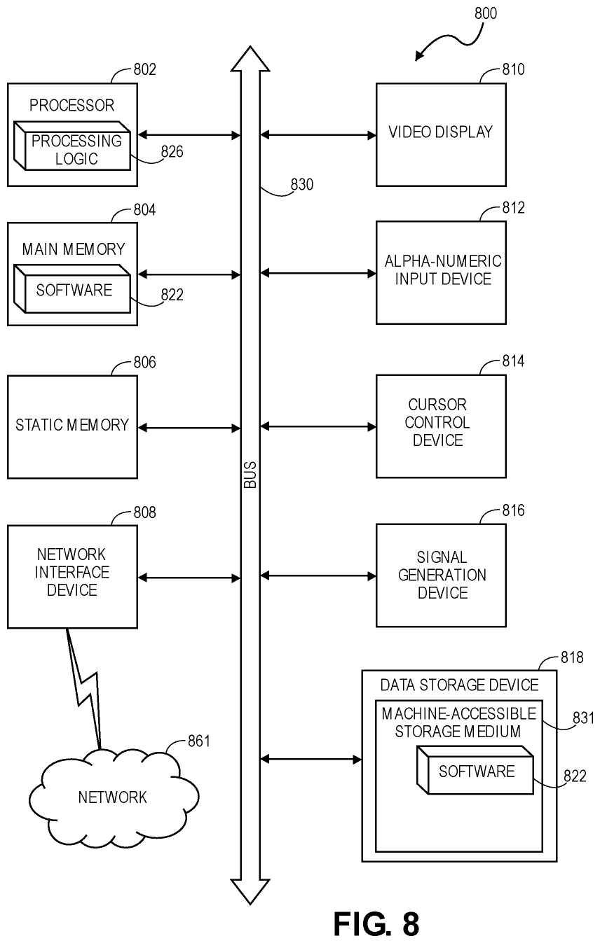

FIG. 8 illustrates a diagrammatic representation of a machine in the exemplary form of a computer system 800 within which a set of instructions, for causing the machine to perform any one or more of the methodologies described herein, may be executed. In alternative embodiments, the machine may be connected (e.g., networked) to other machines in a Local Area Network (LAN), an intranet, an extranet, or the Internet. The machine may operate in the capacity of a server or a client machine in a client-server network environment, or as a peer machine in a peer-to-peer (or distributed) network environment. The machine may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies described herein.

The exemplary computer system 800 includes a processor 802, a main memory 804 (e.g., read-only memory (ROM), flash memory, dynamic random access memory (DRAM) such as synchronous DRAM (SDRAM) or Rambus DRAM (RDRAM), etc.), a static memory 806 (e.g., flash memory, static random access memory (SRAM), MRAM, etc.), and a secondary memory 818 (e.g., a data storage device), which communicate with each other via a bus 830.

Processor 802 represents one or more general-purpose processing devices such as a microprocessor, central processing unit, or the like. More particularly, the processor 802 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processor 802 may also be one or more special-purpose processing devices such as an application specific integrated circuit (ASIC), a field programmable gate array (FPGA), a digital signal processor (DSP), network processor, or the like. Processor 802 is configured to execute the processing logic 826 for performing the operations described herein.

The computer system 800 may further include a network interface device 808. The computer system 800 also may include a video display unit 810 (e.g., a liquid crystal display (LCD), a light emitting diode display (LED), or a cathode ray tube (CRT)), an alphanumeric input device 812 (e.g., a keyboard), a cursor control device 814 (e.g., a mouse), and a signal generation device 816 (e.g., a speaker).

The secondary memory 818 may include a machine-accessible storage medium (or more specifically a computer-readable storage medium) 832 on which is stored one or more sets of instructions (e.g., software 822) embodying any one or more of the methodologies or functions described herein. The software 822 may also reside, completely or at least partially, within the main memory 804 and/or within the processor 802 during execution thereof by the computer system 800, the main memory 804 and the processor 802 also constituting machine-readable storage media. The software 822 may further be transmitted or received over a network 820 via the network interface device 808.

While the machine-accessible storage medium 832 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, and optical and magnetic media.

In accordance with an embodiment of the present disclosure, a machine-accessible storage medium has instructions stored thereon which cause a data processing system to perform a method of exposing a photoresist, developing the photoresist, and etching the underlying substrate. The process may be implemented at least in part with a cluster tool. The cluster tool may include a metrology tool, a develop chamber, and an etch chamber. In an embodiment, the methods disclosed herein allow for improved feedback and/or feed forward control of the developing and etching process in order to improve speed and accuracy compared to conventional methods.

Thus, methods for processing substrates in a cluster tool with a metrology tool, a dry develop chamber, and an etch chamber are described.

What is claimed is:

1. A method of cleaning a chamber, comprising:
flowing a first processing gas into the chamber, wherein the first processing gas reacts with a metal-organic compound in the chamber to form a first volatile compound;
removing the first volatile compound from the chamber;
flowing a second processing gas into the chamber, wherein the second processing gas reacts with a pure metal of the metal-organic compound to form a second volatile compound; and
removing the second volatile compound from the chamber.

2. The method of claim 1, wherein the first processing gas comprises hydrogen.

3. The method of claim 2, wherein the second processing gas comprises chlorine trifluoride, chlorine, or bromine.

4. The method of claim 1, wherein the first processing gas and/or the second processing gas are radicalized by a plasma source.

5. The method of claim 4, wherein the plasma source is an in-situ plasma source, a remote plasma source (RPS), a microwave plasma source, a capacitively coupled plasma (CCP) source, an inductively coupled plasma (ICP) source, a transformer-coupled toroidal plasma (TCTP) source.

6. The method of claim 1, wherein the first processing gas and/or the second processing gas comprise oxygen and one or more of hydrogen, chlorine trifluoride, chlorine, and bromine.

7. The method of claim 1, wherein the first processing gas and the second processing gas are flown into the chamber sequentially.

8. The method of claim 1, wherein the metal-organic compound comprises tin and oxygen.

9. The method of claim 1, wherein the chamber is one chamber in a cluster tool that comprises two or more of a metrology tool, a front end module, a develop chamber, an etch chamber, or a deposition chamber, and wherein the chamber is a photoresist development chamber, a photoresist deposition chamber, a wafer-transfer chamber, or a load lock.

10. The method of claim 1, wherein the first processing gas and/or the second processing gas further comprise one or more of argon, helium, and nitrogen.

11. A method of cleaning a chamber with metal-organic deposits on one or more interior surfaces, comprising:
flowing a first processing gas into the chamber, wherein the first processing gas comprises hydrogen, and wherein the hydrogen reacts with the metal-organic deposits to form first volatile species, and wherein at least some of the first volatile species decomposes to redeposit metal-containing material on interior surfaces of the chamber; and
flowing a second processing gas into the chamber, wherein the second processing gas comprises chlorine, and wherein the chlorine reacts with the metal-containing material to form a second volatile specie.

12. The method of claim 11, wherein the first processing gas and/or the second processing gas are radicalized by a plasma source.

13. The method of claim 11, wherein the first processing gas and/or the second processing gas further comprise oxygen.

14. The method of claim 11, wherein a wafer temperature within the chamber is between 20° C. and 100° C.

15. The method of claim 11, wherein a pressure within the chamber is between 1 mTorr and 10 Torr.

16. The method of claim 11, wherein the chamber is one chamber in a cluster tool that comprises two or more of a metrology tool, a front end module, a develop chamber, an etch chamber, or a deposition chamber, and wherein the chamber is a photoresist development chamber, a photoresist deposition chamber, a wafer-transfer chamber, or a load lock.

17. A load lock, comprising:
a chamber with sidewalls, a top, and a bottom;
a plurality of slot regions for supporting substrates;
a remote plasma source (RPS); and
a plurality of lines between the RPS and the chamber, wherein each line couples the RPS to one of the plurality of slot regions.

18. The load lock of claim 17, wherein the lines pass through sidewalls of the chamber.

19. The load lock of claim 18, wherein each line ends at a distribution plate that is within one of the slot regions.

20. The load lock of claim 17, wherein the load lock is part of a cluster tool that comprises two or more of a metrology tool, a front end module, a develop chamber, an etch chamber, or a deposition chamber.
